(19) United States
(12) Patent Application Publication
(10) Pub. No.: US 2013/0342746 A1
(43) Pub. Date: Dec. 26, 2013

(54) DISPLAY SYSTEM AND IMAGE PICKUP SYSTEM

(71) Applicant: Sony Corporation, Tokyo (JP)

(72) Inventors: Toshiaki Ueda, Saitama (JP); Nobuharu Murashima, Tokyo (JP)

(73) Assignee: SONY CORPORATION, Tokyo (JP)

(21) Appl. No.: 13/900,625

(22) Filed: May 23, 2013

(30) Foreign Application Priority Data
Jun. 22, 2012 (JP) 2012-141158

(51) Int. Cl. H04N 5/225; H05K 5/02; H05K 5/00

(52) U.S. Cl. CPC H04N 5/2252; H05K 5/0017; H05K 5/0217
USPC 348/333.01; 361/679.01

(57) ABSTRACT

A display system includes: a display unit; a holding member containing the display unit; and an attaching member provided between the display unit and the holding member. The attaching member includes a rim section opposed to a side surface of the display unit, a first attaching section provided in the rim section and configured to be fixed to the holding member, and a second attaching section provided in the rim section and configured to be held between the rim section and the holding member by elasticity.

### BACKGROUND

The present disclosure relates to a display system containing a display unit such as a liquid crystal display unit and an organic EL (electroluminescence) display unit in a holding member (such as a housing and a cabinet), and to an image pickup system including the display system.

A display unit using liquid crystal, organic EL, or the like is mounted on a camera, a television, a PC (personal computer), or the like. For example, in Japanese Unexamined Patent Application Publication No. 2007-3693, a member-laminated structure is integrally modularized by configuring the member-laminated structure by sandwiching a framework flat member between a display unit and a light guide unit, and by wrapping a side edge of the member-laminated structure with a bendable enclosure such as rubber.

### SUMMARY

In Japanese Unexamined Patent Application Publication No. 2007-3693, an end of the framework flat member is extended in a horizontal direction around the display unit, and the extended end is fitted in a groove inside the enclosure. This therefore is disadvantageous in that a width of a bezel region has to be widened for a fitting depth (groove depth) of the framework flat member.

It is desirable to provide a display system capable of narrowing a bezel, and an image pickup system including the display system.

According to an embodiment of the present disclosure, there is provided a display system including: a display unit; a holding member containing the display unit; and an attaching member provided between the display unit and the holding member. The attaching member includes a rim section opposed to a side surface of the display unit, a first attaching section provided in the rim section and configured to be fixed to the holding member, and a second attaching section provided in the rim section and configured to be held between the rim section and the holding member by elasticity.

In the display system according to the above-described embodiment of the present disclosure, the attaching member is provided between the display unit and the holding member that contains the display unit. The attaching member includes the rim section opposed to the side surface of the display unit, and the first attaching section and the second attaching section are provided in the rim section. The first attaching section is configured to be fixed to the holding member. The second attaching section is configured to be held between the rim section and the holding member by elasticity. Here, since the rim section of the attaching member is provided in opposition to the side surface of the display unit, an occupied width of the attaching member in a bezel region is narrowed, compared to an existing display system that an end of a framework flat member is extended in a horizontal direction around a display unit.

According to an embodiment of the present disclosure, there is provided an image pickup system provided with an image pickup optical system, an image pickup device, and a display system that displays one of a subject image formed by the image pickup optical system and an image picked up by the image pickup device. The display system includes: a display unit; a holding member containing the display unit; and an attaching member provided between the display unit and the holding member. The attaching member includes a rim section opposed to a side surface of the display unit, a first attaching section provided in the rim section and configured to be fixed to the holding member, and a second attaching section provided in the rim section and configured to be held between the rim section and the holding member by elasticity.

In the image pickup system according to the above-described embodiment of the present disclosure, the subject image formed by the image pickup optical system or the image picked up by the image pickup device is displayed by the display system.

According to the display system of the above-described embodiment of the present disclosure, the rim section of the attaching member is provided in opposition to the side surface of the display unit, and the first attaching section configured to be fixed to the holing member and the second attaching section configured to be held between the rim section and the holding member by elasticity are provided in the rim section. Therefore, the bezel is allowed to be narrowed. Accordingly, configuring the image pickup system by using the display system allows a screen size to be increased while keeping portability.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a perspective view illustrating an appearance of an image pickup system according to a first embodiment of the present disclosure in a state that an openable and closable panel is closed.

FIG. 2 is a perspective view illustrating an appearance of the image pickup system illustrated in FIG. 1 in a state that the openable and closable panel is opened.

FIG. 3 is a perspective view illustrating an appearance of the image pickup system illustrated in FIG. 1 viewed from a different direction.

FIG. 4 is a block diagram illustrating a circuit configuration of the image pickup system illustrated in FIG. 1.

FIG. 5 is a perspective view illustrating a state that a display unit illustrated in FIG. 3 is removed from a cabinet.

FIG. 6 is a perspective view illustrating the disassembled display unit illustrated in FIG. 5 together with an attaching member.

FIG. 7 is a perspective view illustrating a whole configuration of the attaching member illustrated in FIG. 6.

FIG. 8 is an enlarged perspective view illustrating a first attaching section illustrated in FIG. 7.

FIG. 9 is an enlarged perspective view illustrating a second attaching section in a long side illustrated in FIG. 7.

FIG. 10 is an enlarged perspective view illustrating a second attaching section in a short side illustrated in FIG. 7.

FIG. 11 is a cross-sectional view illustrating a state of fitting of a rim section into a cabinet in the first attaching section illustrated in FIG. 8.

FIG. 12 is a cross-sectional view illustrating a state of fitting of the rim section into the cabinet in the vicinity of the first attaching section illustrated in FIG. 8.

FIG. 13 is a cross-sectional view illustrating a state of attachment of the rim section to the cabinet in the second attaching section illustrated in FIG. 9.

FIG. 14 is a cross-sectional view illustrating a state of attachment of the rim section to the cabinet in the vicinity of the second attaching section illustrated in FIG. 9.

FIG. 15 is a cross-sectional view illustrating a state of attachment of the rim section to the cabinet in the second attaching section illustrated in FIG. 10.

FIG. 16 is a perspective view illustrating a step of a method of manufacturing a display system illustrated in FIG. 5.

FIG. 17 is a perspective view illustrating a step following the step of FIG. 16.

FIG. 18 is a perspective view illustrating a step following the step of FIG. 17.

FIG. 19 is a cross-sectional view for explaining a width of a bezel region in the display system illustrated in FIG. 5.

FIG. 20 is a cross-sectional view for explaining a width of a bezel region in an existing display system.

FIG. 21 is a perspective view illustrating a disassembled display unit and a disassembled attaching member of a display system according to a second embodiment of the present disclosure.

FIG. 22 is a perspective view illustrating a whole configuration of the attaching member illustrated in FIG. 21.

FIG. 23 is an enlarged perspective view illustrating a first attaching section illustrated in FIG. 22.

FIG. 24 is an enlarged perspective view illustrating a second attaching section in a long side illustrated in FIG. 22.

FIG. 25 is an enlarged perspective view illustrating a second attaching section in a short side illustrated in FIG. 22.

FIG. 26 is a cross-sectional view illustrating a state of fitting of a rim section into a holding member in the first attaching section illustrated in FIG. 23.

FIG. 27 is a cross-sectional view illustrating a state of attachment of the rim section to the holding member in the vicinity of the first attaching section illustrated in FIG. 23.

FIG. 28 is a cross-sectional view illustrating a state of attachment of the rim section to the holding member in the second attaching section illustrated in FIG. 24.

FIG. 29 is a cross-sectional view illustrating a state of attachment of the rim section to the holding member in the vicinity of the second attaching section illustrated in FIG. 24.

FIG. 30 is a cross-sectional view illustrating a state of attachment of the rim section to the holding member in the second attaching section illustrated in FIG. 25.

FIG. 31 is a perspective view illustrating a whole configuration of an attaching member according to a modification 1.

FIG. 32 is a perspective view illustrating a whole configuration of an attaching member according to a modification 2.

### DETAILED DESCRIPTION

Some embodiments of the present disclosure will be described in detail with reference to the drawings.

1. First Embodiment (example in which an attaching member is in the shape of a tray configured of a bottom surface section and a rim section)
2. Second Embodiment (example in which an attaching member is in the shape of a window frame configured of only a rim section)
3. Modification 1 (example in which a first attaching section is provided in a long side in the first embodiment)
4. Modification 2 (example in which a first attaching member is provided in a long side in the second embodiment)

### First Embodiment

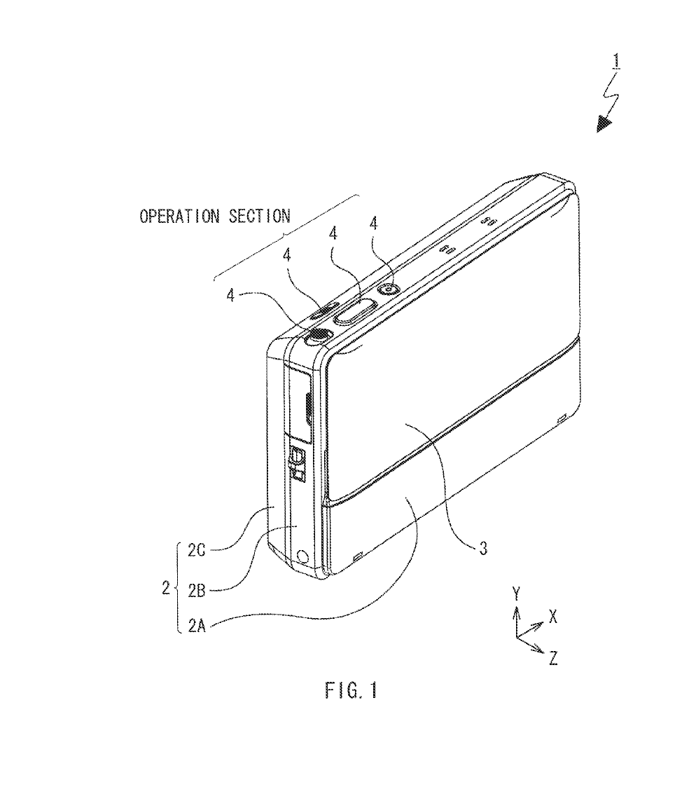

FIG. 1 illustrates an appearance of an image pickup system (digital still camera) according to a first embodiment of the present disclosure viewed from a subject side. The image pickup system 1 may have, for example, an openable and closable panel 3 vertically slidable on the front surface of a main body section 2. An operation section 4 is arranged on the upper surface of the main body section 2. The operation section 4 may include, for example, a power button for turning on the power, a shutter button operated at the time of shooting, and a zoom mechanism for zooming.

In the following description and the drawings, a longitudinal direction (Z), a vertical direction (Y), and a horizontal direction (X) are indicated by directions viewed from a photographer at the time of shooting by the image pickup system 1. Therefore, the subject side is the front side, and the photographer side is the rear side. It is to be noted that the longitudinal direction (Z), the vertical direction (Y), and the horizontal direction (X) are used for convenience, and applications of the present disclosure are not limited to these directions.

The main body section 2 may have, for example, a front panel 2A, an intermediate rim 2B, and a cabinet 2C. The front panel 2A, the intermediate rim 2B, and the cabinet 2C are connected in this order in the longitudinal direction Z.

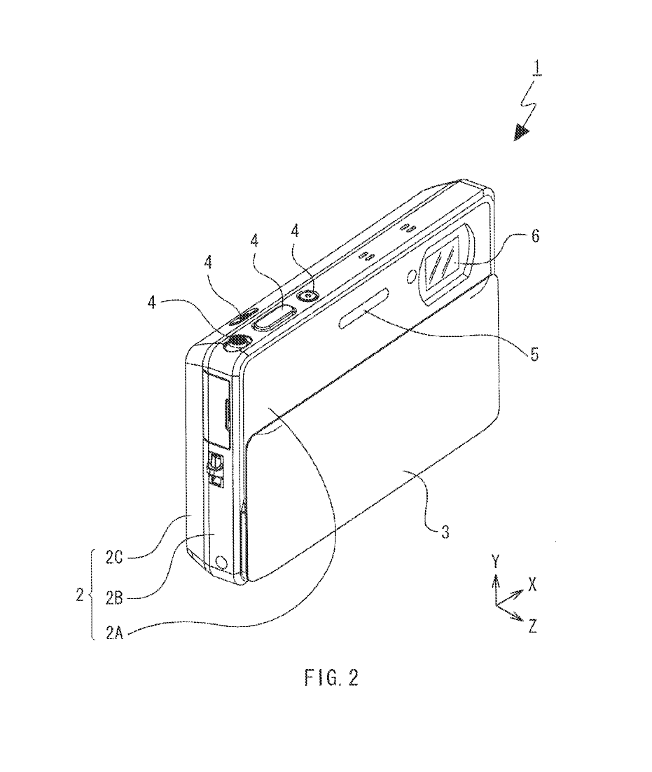

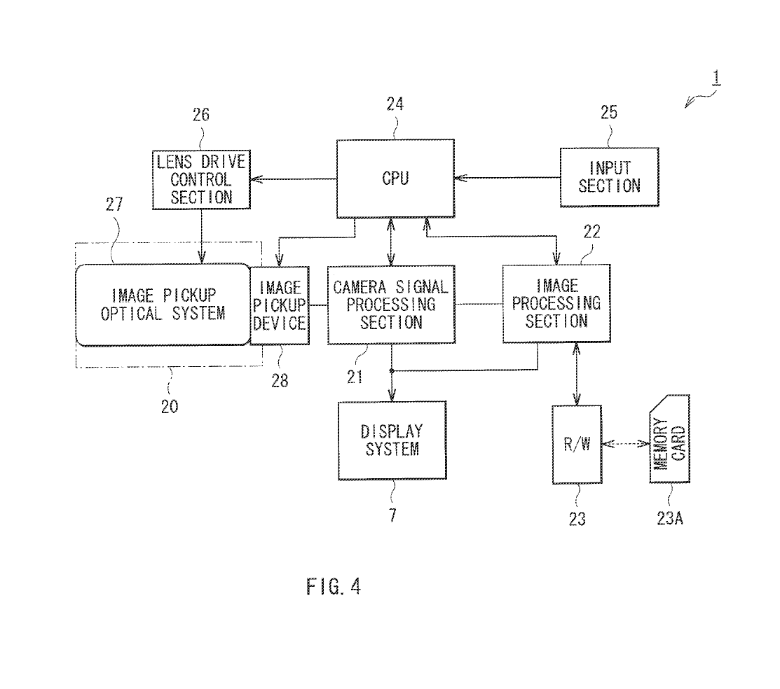

FIG. 2 illustrates a state that the openable and closable panel 3 is opened. On the upper end of the front surface of the main body section 2, a flash 5 irradiating fill light at the time of shooting and a shooting lens 6 for forming an image of a subject may be arranged horizontally in line. In the main body section 2 located behind the shooting lens 6, a lens or a group of lenses (not illustrated) are arranged along a light axis as an image pickup optical system (not illustrated in FIG. 2, and see FIG. 4).

The flash 5 and the shooting lens 6 are opened and closed by sliding the openable and closable panel 3 in a vertical direction. A subject is allowed to be shot by moving the openable and closable panel 3 downward and opening the flash 5 and the shooting lens 6. The subject is not allowed to be shot by moving the openable and closable panel 3 upward and closing the flash 5 and the shooting lens 6.

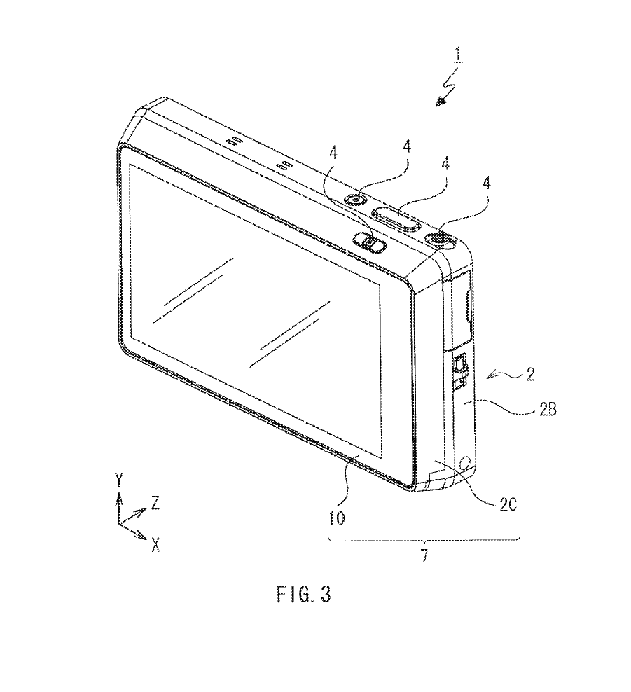

FIG. 3 illustrates an appearance of the image pickup system 1 viewed from the photographer side. On the rear surface of the main body section 2, a display system 7 is provided. The display system 7 displays a subject image formed by the image pickup optical system or an image picked up by an image pickup device. In addition thereto, the display system 7 displays a state of operation by a user with respect to the operation section 4, various data memorized in an embedded memory of the main body section 2 and an external memory, and the like. The display system 7 may have, for example, a configuration in which a display unit 10 such as a liquid crystal display unit and an organic EL display unit is contained in the cabinet 2C.

FIG. 4 illustrates an example of a circuit configuration of the image pickup system 1. The image pickup system 1 may have, for example, a camera block 20 performing an image pickup function, a camera signal processing section 21, an image processing section 22, the display system 7, an R/W (reader/writer) 23, a CPU (central processing unit) 24, an input section 25, and a lens drive control section 26.

The camera block 20 may have, for example, an image pickup optical system 27 including the group of lenses (not illustrated) and the like and an image pickup device 28 such as a CCD (charge coupled device) and a CMOS (complementary metal-oxide semiconductor) sensor (not illustrated either).

The camera signal processing section 21 may perform, for example, various signal processing such as analog-digital conversion with respect to an output signal from the image pickup device 28, denoising, image correction, and conversion to a luminance signal or a color-difference signal.

The image signal processing section 22 performs compression coding and extension decoding processing of an image signal based on a prescribed image data format, conversion processing of data specifications such as resolution, and the like.

The R/W 23 performs writing image data coded by the image signal processing section 22 in a memory card 23A, and reading image data recorded in the memory card 23A. The memory card 23A may be, for example, a semiconductor memory attachable and detachable with respect to a slot connected to the R/W 23.

The CPU 24 has a function as a control processing section to control the whole image pickup system 1. The CPU 24 controls each circuit block based on an instruction input signal or the like from the input section 25.

The input section 25 outputs an instruction input signal according to operation of the operation section 4 by the user to the CPU 24.

The lens drive control section 26 may control, for example, a motor (not illustrated) that drives the respective lenses of the image pickup optical system 27 based on a control signal from the CPU 24.

Next, a description will be given of operation of the image pickup system 1 based on FIG. 4.

In a shooting-standby state, under the control by the CPU 24, a signal of an image shot in the camera block 20 is outputted to the display system 7 through the camera signal processing section 21 and is displayed as an image through a camera (a so-called “camera-through image”). Further, in the case where an instruction input signal for zooming from the input section 25 is inputted, the CPU 24 outputs a control signal to the lens drive control section 26, and a prescribed lens of the image pickup optical system 27 is moved based on control of the lens drive control section 26.

In the case where an unillustrated shutter of the camera block 20 is operated by the instruction input signal from the input section 25, the signal of the shot image is outputted from the camera signal processing section 21 to the image signal processing section 22, is subject to compression coding, and is converted to digital data having a prescribed data format. The converted data is outputted to the R/W23, and is written in the memory card 23A.

It is to be noted that focusing may be performed by moving a prescribed lens of the image pickup optical system 27 by the lens drive control section 26 based on a control signal from the CPU 24 in the case where, for example, a shutter button of the input section 25 is half pressed or is entirely pressed for recording (shooting).

In the case where the image data recorded in the memory card 23A is reproduced, according to an operation to the input section 25, prescribed image data is read from the memory card 23A by the R/W23, extension decoding processing is performed by the image processing section 22, and subsequently, a reproduced image signal is outputted to the display system 7, and a reproduced image is displayed.

A description will be given in detail of the display system 7 illustrated in FIG. 3. As described above, the display system 7 may have the configuration in which the display unit 10 such as a liquid crystal display unit and an organic EL display unit is contained in the cabinet 2C. The cabinet 2C corresponds to a specific example of “holding member” in one embodiment of the disclosure.

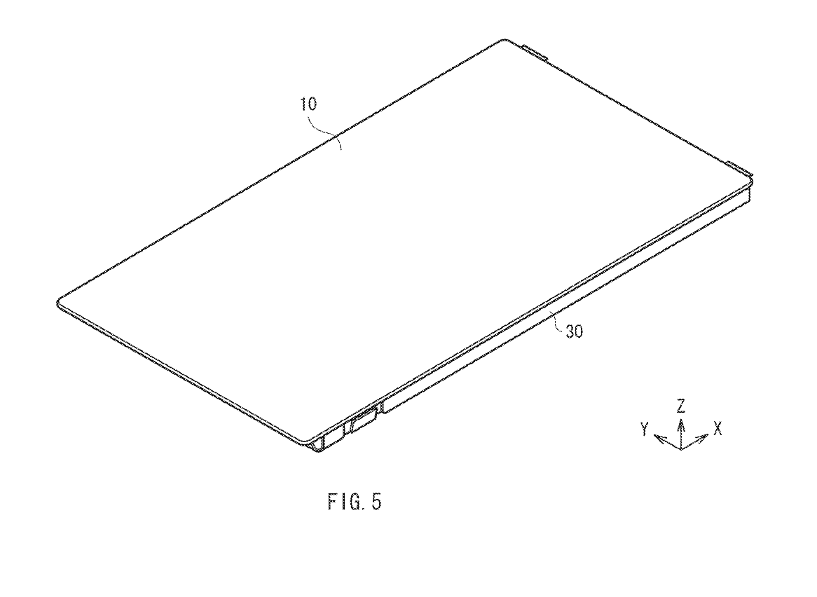

FIG. 5 illustrates a state that the display unit 10 is removed from the cabinet 2C. As illustrated in FIG. 5, the display unit 10 is contained in the cabinet 2C in a state that the display unit 10 is mounted on an attaching member 30. The attaching member 30 is provided between the display unit 10 and the cabinet 2C, and has a function as a bracket holding the display unit 10 in a prescribed position in the cabinet 2C. For details of the attaching member 30, a description will be given later.

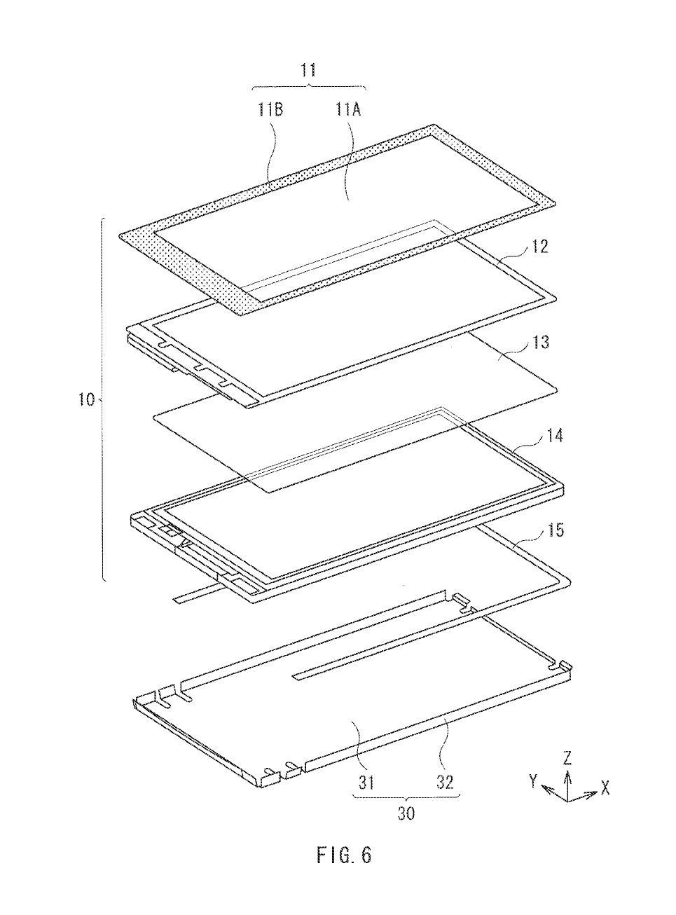

FIG. 6 illustrates the disassembled display unit 10 illustrated in FIG. 5 together with the attaching member 30. The display unit 10 may have, for example, a front surface plate (top plate) 11, a touch panel 12, an adhesive layer 13, and a display 14 in this order from the front to the backward in the Z direction. The foregoing attaching member 30 is provided behind the display unit 10 (specifically, behind the display 14).

The front surface plate 11 may be provided to improve strength of the display 14 and the touch panel 12, protect the front surface, and improve design, for example. For example, the front surface plate 11 may be configured of a transparent plate made of glass, reinforced glass, a resin, or the like. Examples of the resin configuring the front surface plate 11 may include acryl, polycarbonate, and polyethylene terephthalate (PET).

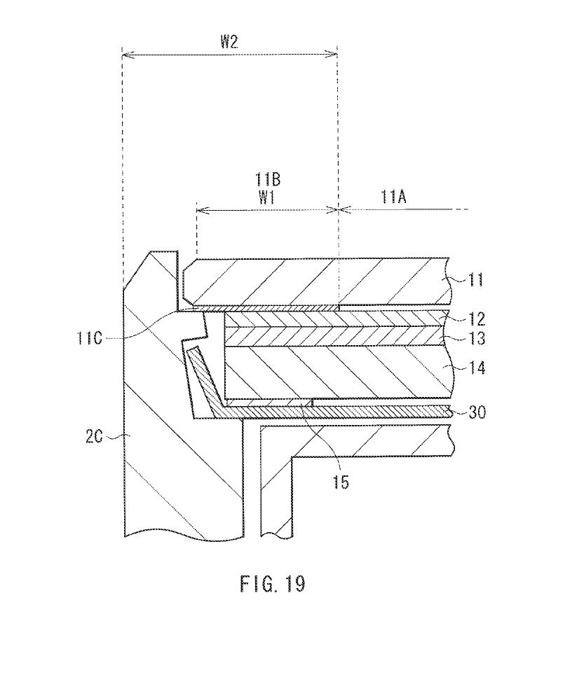

The front surface plate 11 may have, for example, a transparent section 11A and a non-translucent section 11B. The transparent section 11A is provided in a central region of the front surface plate 11 to oppose to a display region of the display 14, and is configured of a transparent plate itself of the front surface plate 11. The non-translucent section 11B has a function as a so-called bezel region that hides wiring, a circuit, and the like in a peripheral region of the display 14 and a peripheral region of the touch panel 12 and adjusts appearance of the display unit 10. The non-translucent section 11B is arranged in a peripheral region of the front surface plate 11, and may have, for example, a configuration in which a non-translucent layer (not illustrated in FIG. 6, and see FIG. 19) made of an opaque material such as a metal, a pigment, and a colorant is provided on the rear surface of the transparent plate of the front surface plate 11. It is to be noted that the non-translucent layer may be provided on the front surface of the front surface plate 11.

The touch panel 12 may be an input device on which, for example, a capacitance-type touch sensor is mounted. An effective detection region of the touch panel 12 almost corresponds with an effective display region of the display 14. A detection surface (input surface) of the touch panel 12 may be, for example, adhered to the front surface plate 11 with an adhesive layer (not illustrated) made of a transparent glue in between. The rear surface of the touch panel 12 may be adhered to the front surface (image display surface) side of the display 14 by the adhesive layer 13 made of a gel sheet.

Desirably, the adhesive layer 13 may be provided over the whole surface between the touch panel 12 and the display 14. In general, a thick structural object has a so-called air-gap-free structure in which each layer is adhered to each other with the use of an elastic gel adhesive to prevent existence of air. The air-gap-free structure has an advantage that internal reflection is less likely to occur in the range from the front surface of the display 14 to the front surface (image display surface) of the front surface plate 11 and an easily viewable image is allowed to be provided. Desirably, the adhesive layer (not illustrated) made of a transparent glue that secures adherence between the touch panel 12 and the front surface plate 11 may be provided over the whole surface between the touch panel 12 and the front surface plate 11 as the adhesive layer 13 is.

The display 14 may include a liquid crystal display panel having a liquid crystal layer between two substrates made of, for example, glass. On one substrate, a TFT (thin film transistor) driving each pixel and a pixel electrode are arranged, and a drive circuit for supplying an image signal or the like to each pixel and the like are provided. On the other substrate, for example, a transparent electrode may be provided, and respective color filters of three primary colors (R, G, and B) may be formed for every pixel. Periphery of the liquid crystal layer is sealed by a sealing material. On the front surface of the display 14, a rectangular polarizer (not illustrated) having a size slightly smaller than that of the display 14 is provided. On the rear surface of the display 14, a similar polarizer (not illustrated) is provided as well. In the vicinity of the display 14, although not illustrated, a backlight unit including a light source which may be configured of an LED (light emitting diode) or the like, a light guide plate, an optical function sheet, a heat release member, and the like may be arranged. It is to be noted that the display 14 is not limited to the foregoing liquid crystal display panel, and may be configured of, for example, an organic EL panel.

The attaching member 30 may have a shape of a tray having a bottom surface section 31 covering the rear surface (specifically, the rear surface of the display section 14) of the display unit 10 and a rim section 32 rising on four sides of the bottom surface section 31. A shape of the attaching member 30 in the XY plane may be, for example, a rectangle having longer sides in one direction (X direction) as that of the display unit 10.

The bottom surface section 31 is a flat member having the same shape as that of the rear surface of the display unit 10. The rear surface of the display unit 10 (specifically, the rear surface of the display section 14) is adhered to the bottom surface section 31 by the adhesive layer 15 such as a double-faced tape. It is sufficient for the adhesive layer 15 to be provided so that the display 14 is fixed on the bottom surface section 31, and the adhesive layer 15 is not necessarily provided over the whole surface of the rear surface of the display 14. For example, the adhesive layer 15 may be provided along three sides other than one side connected to a flexible printed circuit of the display 14.

The rim section 32 may have, for example, a wall-like shape that vertically rises from the end edge of the bottom surface section 31 along side surfaces of the display unit 10, and is opposed to the side surfaces of the display unit 10. The rim section 32 is provided over the whole circumference of the end edge of the bottom surface section 31 to surround the side surfaces of the display unit 10.

Preferably, such an attaching member 30 may be made of a plate such as stainless steel, since this is advantageous in terms of reinforcement and countermeasure against static electricity, and the attaching member 30 is allowed to be reduced in thickness. In the case where thickness limitation of the attaching member 30 is not tight, the attaching member 30 may be made of a resin. In this case, the rim section 32 and the bottom surface section 31 may be integrally formed of a resin.

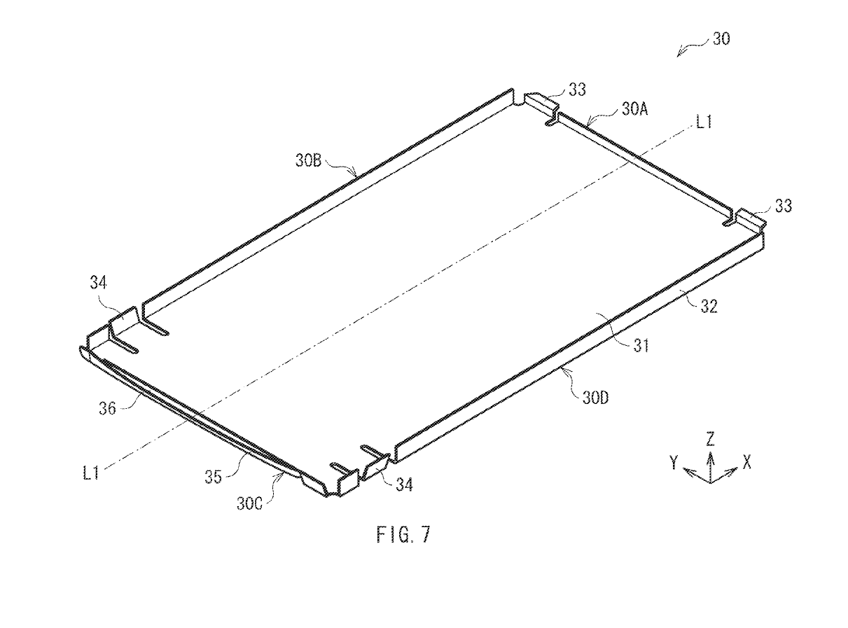

FIG. 7 illustrates an enlarged whole configuration of the attaching member 30 illustrated in FIG. 6. First attaching sections 33 are provided in one short side 30A of the rim section 32, second attaching sections 34 are provided in two opposing long sides 30B and 30D, and a second attaching section 35 is provided in the other short side 30C. The first attaching sections 33 are fixed to a cabinet 2C. The second attaching sections 34 and 35 are held between the rim section 32 and the cabinet 2C by elasticity. Thereby, in the display system 7, the bezel is allowed to be narrowed.

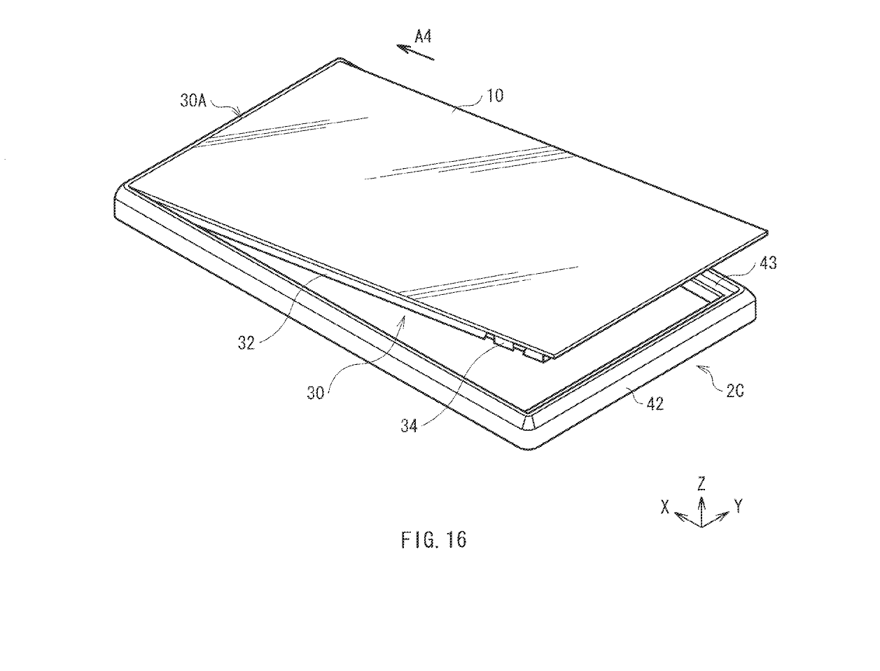

Desirably, the first attaching sections 33 may be provided, for example, in both ends of the short side 30A. Thereby, in an assembly step (see FIG. 16) described later, rotation in the XY plane is allowed to be suppressed. Further, desirably, the first attaching sections 33 may be arranged in the same shape, being equally distant from both ends of the short side 30A (arranged line-symmetrically with respect to a center line L1 in the Y direction of the attaching member 30).

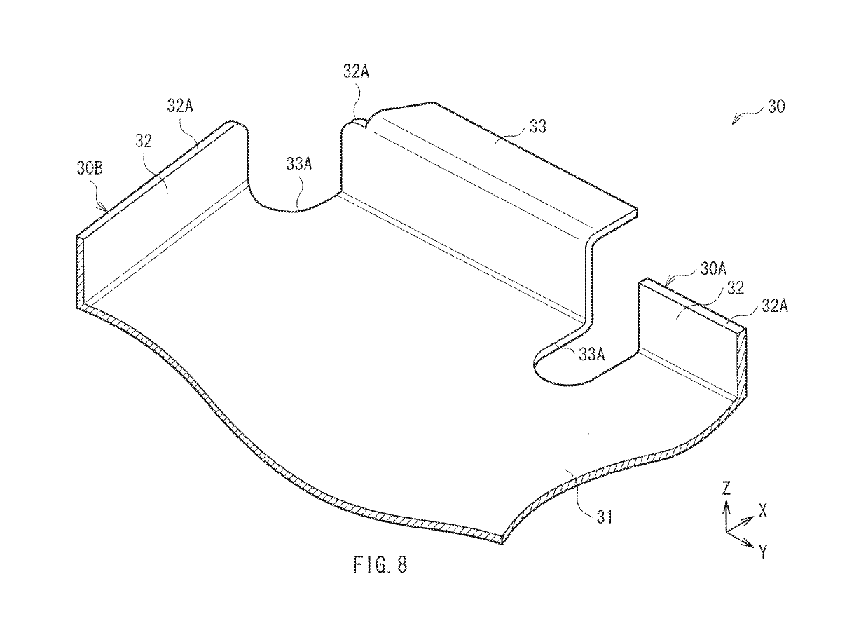

As illustrated in an enlarged view of FIG. 8, specifically, the first attaching section 33 is a nail extending outward from one end (upper end) 32A in a width direction of the rim section 32. The first attaching section 33 may be, for example, bent perpendicular to the rim section 32.

It is to be noted that, since portions where the first attaching sections 33 are provided in the rim section 32 are separated from other portions by a groove 33A to absorb elastic deformation at the time of attachment to the main body section 2 (cabinet 2C).

Desirably, the second attaching sections 34 may be provided, for example, in ends on the short side 30C side of the long sides 30B and 30D. Further, desirably, the second attaching sections 34 may have the same shape, and are may be arranged in positions opposed to each other in the long sides 30B and 30D (arranged line-symmetrically with respect to the center line L1 in the Y direction of the attaching member 30).

The second attaching section 35 may be provided in upper portion of the rim section 32 in almost whole area of the short side 30C.

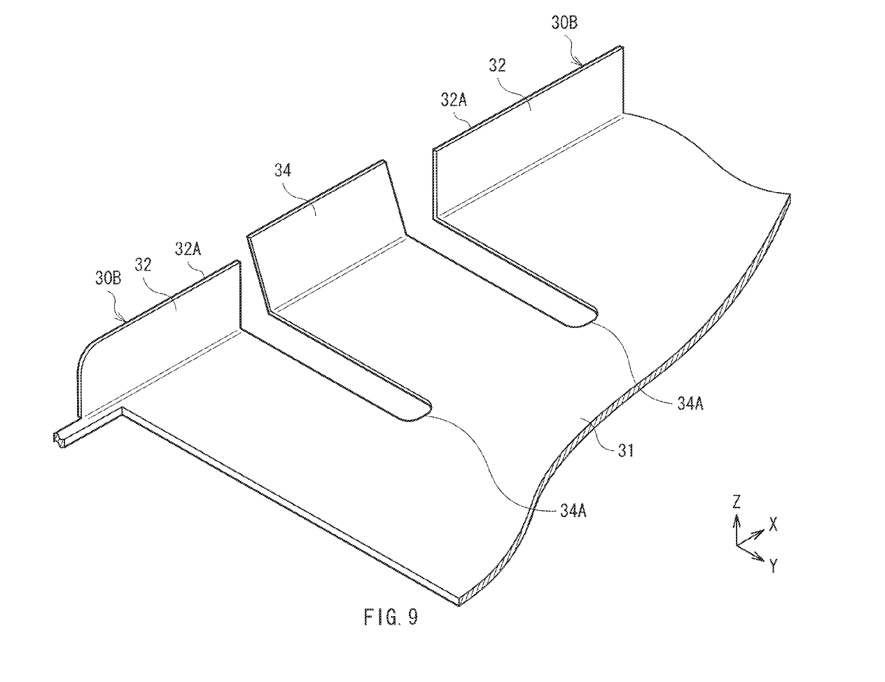

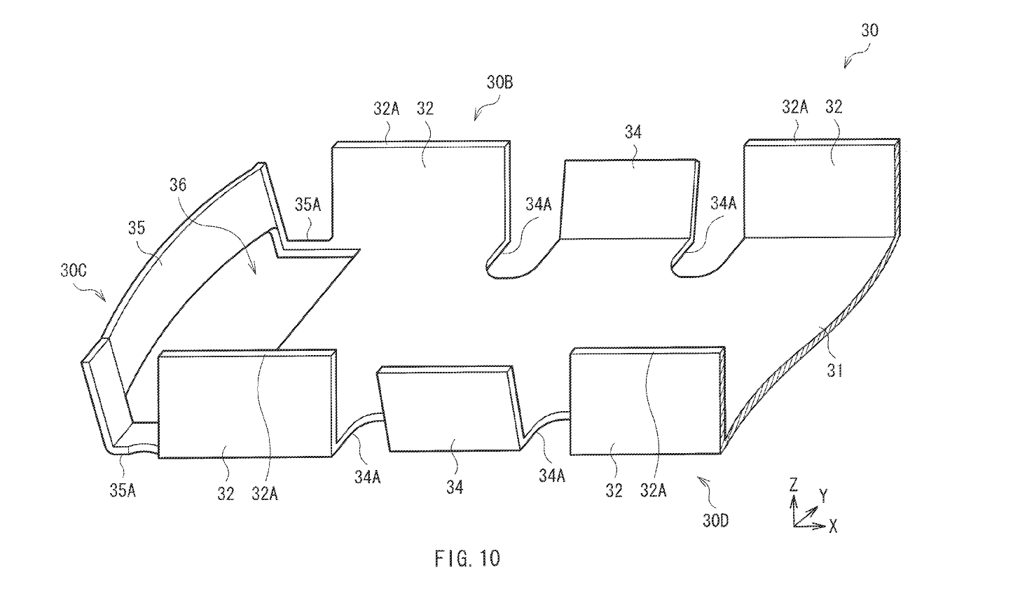

The second attaching section 34 is, specifically, as illustrated in an enlarged view of FIG. 9, a plate spring obtained by inclining part of the rim section 32 outward. The second attaching section 35 is, specifically, as illustrated in an enlarged view of FIG. 10, a plate spring obtained by inclining or curving part of the rim section 32 outward. By forming the second attaching sections 34 and 35 as the plate springs as described above, dimension variation due to a common difference of parts is allowed to be resolved.

It is to be noted that, portions where the second attaching sections 34 are provided in the rim section 32 are separated from other portions by a groove 34A to absorb elastic deformation at the time of attachment to the main body section 2 (cabinet 2C). Similarly, a portion where the second attaching section 35 is provided in the rim section 32 is separated from other portions by a groove 35A to absorb dimension variation due to the common difference of parts at the time of attachment to the main body section 2 (cabinet 2C).

Further, the short side 30C is provided with an opening 36. The opening 36 is provided to give passage to a flexible printed circuit (not illustrated) connected to the display unit 10, and is obtained by hollowing a lower portion of the rim section 32 in the short side 30C and an end of the bottom surface section 31 adjacent thereto.

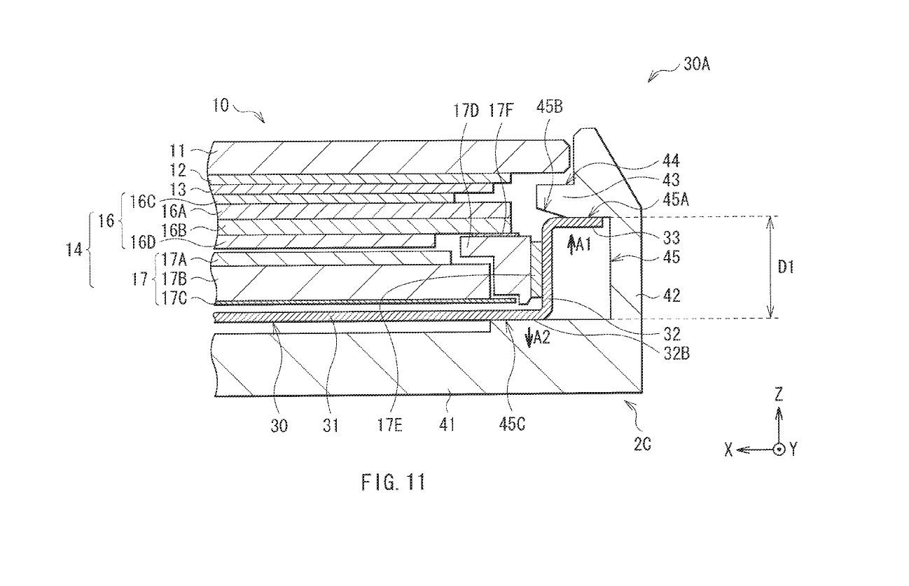

FIG. 11 illustrates a state of fitting of the rim section 32 into the cabinet 2C in the first attaching section 33. The cabinet 2C may have, for example, a bottom surface section 41 and a side surface section 42. The bottom surface section 41 is opposed to the bottom surface section 31 of the attaching member 30. The side surface section 42 has a wall-like shape that vertically rises from the bottom surface section 41 along the side surfaces of the display unit 10 and the rim section 32 of the attaching member 30.

The side surface section 42 is provided with a flange 43 extending toward inside of the cabinet 2C. The front surface plate 11 of the display unit 10 is moderately fitted in a step section 44 above the flange 43. On the other hand, a concave section 45 receiving the rim section 32 is provided under the flange 43. The flange 43, the step section 44, and the concave section 45 are continuously provided over the whole circumference of the inner surface of the cabinet 2C. However, each cross-sectional shape thereof varies according to locations on the side surface section 42 based on the shape of the rim section 32 of the attaching member 30 (specifically, the first attaching sections 33 and the second attaching sections 34 and 35).

In the short side 30A of the attaching member 30, a contacting section 45A with which the nail of the first attaching section 33 is contacted is provided on the upper surface of the concave section 45 (lower surface of the flange 43). By contacting the contacting section 45A with the first attaching section 33, upward movement (arrow A1) of the attaching member 30 is allowed to be restricted.

The contacting section 45A may be, for example, a flat surface capable of making surface-contact with the first attaching section 33. Desirably, an inclining section 45B as a fitting guide for the first attaching section 33 may be provided at the entrance of the contacting section 45A.

A seat section 45C receiving the other end (lower end) 32B in the width direction of the rim section 32 is provided on the lower surface of the concave section 45. By contacting the seat section 45C with the lower end 32B of the rim section 32, downward movement (arrow A2) of the attaching member 30 is allowed to be restricted. Therefore, it is sufficient for the front surface plate 11 to be moderately fitted in the step section 44 above the flange 43, and it is not necessary for the front surface plate 11 to be brought into contact with the flange 43 or the like.

Preferably, distance D1 between the contacting section 45A and the seat section 45C may correspond to a height of the rim section 32 (distance between the first attaching section 33 and the lower end 32B). Thereby, by contacting the first attaching section 33 with the contacting section 45A and by contacting the lower end 32B of the rim section 32 with the seat section 45C, the rim section 32 is fitted in the concave section 45. Therefore, slip in the Z direction of the attaching member 30 and the display unit 10 is allowed to be suppressed.

It is to be noted that FIG. 11 to FIG. 15 illustrate, for example, a liquid crystal display panel 16 and a backlight unit 17 as an example of a detailed configuration of the display 14. The liquid crystal display panel 16 may have, for example, a liquid crystal layer (not illustrated) between a pair of substrates 16A and 16B. Polarizers 16C and 16D are respectively adhered to the substrates 16A and 16B. The backlight unit 17 may have, for example, an optical sheet 17A, a light guide plate 17B, a reflecting sheet 17C, a light source (not illustrated), a rim part 17D to hold these parts, and a fixing member 17E. The substrate 16B of the liquid crystal display panel 16 is fixed to the rim part 17D by an adhesive layer 17F.

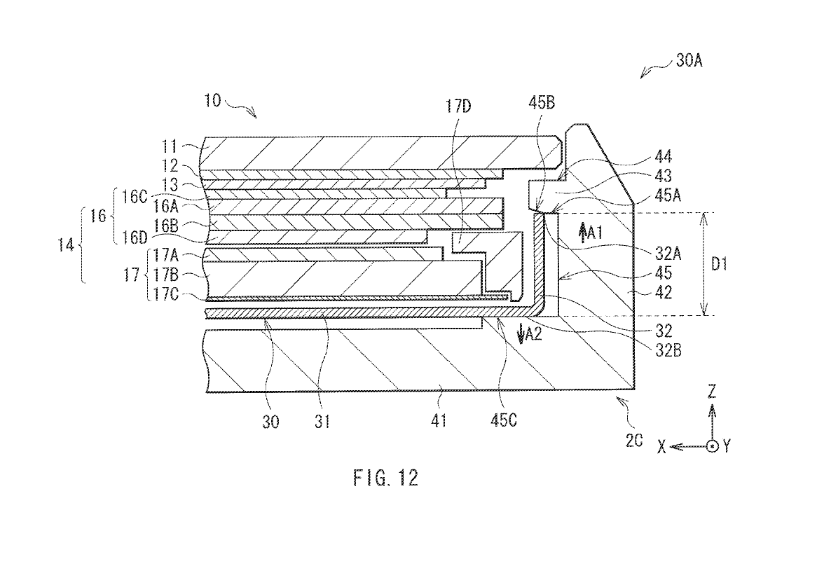

FIG. 12 illustrates a state of fitting of the rim section 32 into the cabinet 2C in the vicinity of the first attaching section 33. In portions other than the first attaching members 33 of the short side 30A, the upper end 32A of the rim section 32 may be contacted with the contacting section 45A. The inclining section 45B as a fitting guide for the upper end 32A of the rim section 32 may be provided at the entrance of the contacting section 45A. The lower end 32B of the rim section 32 may be contacted with the seat section 45C.

The distance D1 between the contacting section 45A and the seat section 45C may correspond to the height of the rim section 32 (distance between the upper end 32A and the lower end 32B of the rim section 32) similarly to the description for the first attaching section 33.

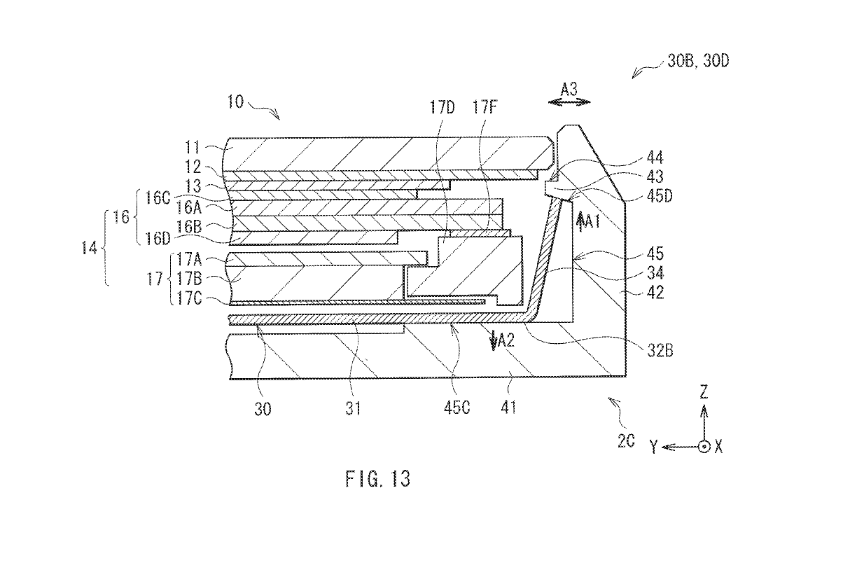

FIG. 13 illustrates a state of attachment of the rim section 32 to the cabinet 2C in the second attaching section 34. In the long sides 30B and 30D of the attaching member 30, a retainer section 45D retaining the plate spring of the second attaching section 34 is provided on the upper surface of the concave section 45. By contacting the retainer section 45D with the second attaching section 34, upward movement (arrow A1) of the attaching member 30 and movement in the XY plane direction (arrow A3) of the attaching member 30 are allowed to be restricted.

Desirably, the retainer section 45D may have an inclined surface as a fitting guide for the second attaching section 34.

The seat section 45C receiving the lower end 32B of the rim section 32 is provided on the bottom surface of the concave section 45. By contacting the seat section 45C with the lower end 32B of the rim section 32, downward movement (arrow A2) of the attaching member 30 is allowed to be restricted. Therefore, it is sufficient for the front surface plate 11 to be moderately fitted in the step section 44 above the flange 43, and it is not necessary for the front surface plate 11 to be brought into contact with the flange 43 or the like.

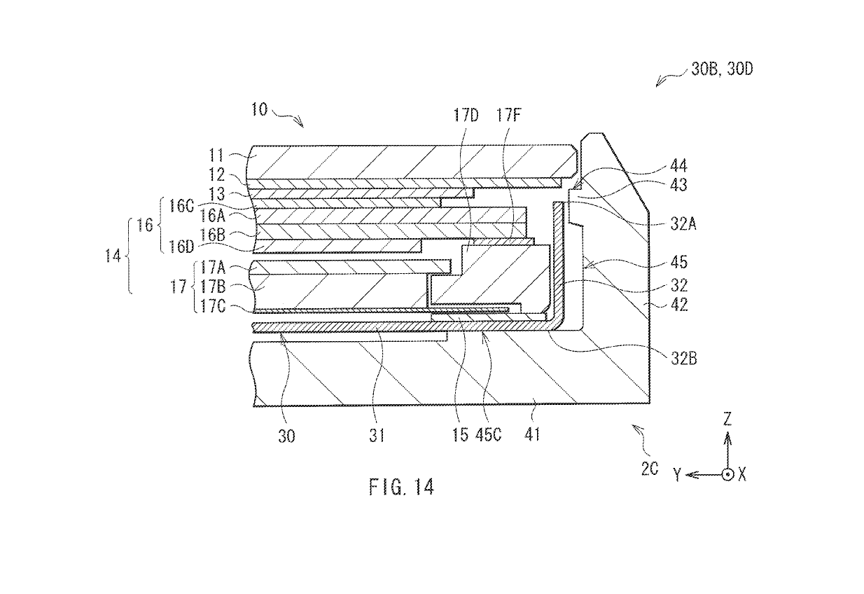

FIG. 14 illustrates a state of attachment of the rim section 32 to the cabinet 2C in the vicinity of the second attaching section 34. In portions other than the second attaching members 34 of the long sides 30B and 30D, the upper end 32A of the rim section 32 is not contacted with any place, and is opened. Thereby, the rim section 32 is allowed to have effect as a shield case to suppress static electricity. The lower end 32B of the rim section 32 may be contacted with the seat section 45C.

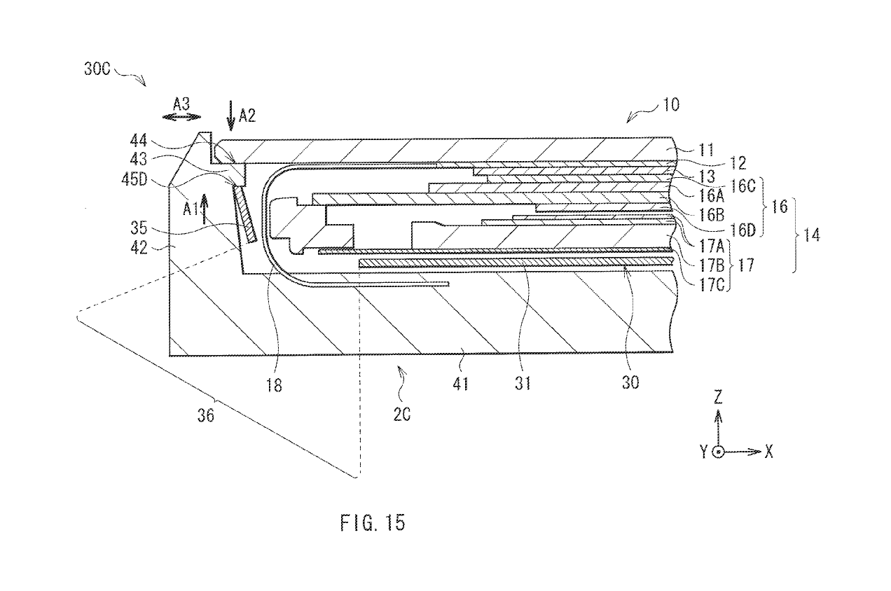

FIG. 15 illustrates a state of attachment of the rim section 32 to the cabinet 2C in the second attaching section 35. In the short side 30C of the attaching member 30, the retainer section 45D retaining the plate spring of the second attaching section 35 is provided on the upper surface of the concave section 45. By contacting the retainer section 45D with the second attaching section 35, upward movement (arrow A1) of the attaching member 30 and movement in the XY plane direction (arrow A3) of the attaching member 30 are allowed to be restricted. A flexible printed circuit 18 is let through the opening 36.

Preferably, in the short side 30C, the step section 44 may receive the end of the front surface plate 11. By contacting the step section 44 with the end of the front surface plate 11, downward movement (arrow A2) of the attaching member 30 and the display unit 10 is allowed to be restricted. It is to be noted that the downward movement is allowed to be sufficiently suppressed only by laying the front surface plate 11 on the step section 44, and fixing by an adhesive or the like is not necessarily performed.

The display system 7 may be manufactured, for example, as follows.

FIG. 16 to FIG. 18 illustrate a method of manufacturing (method of assembling) the display system 7 in the order of steps. First, as illustrated in FIG. 6, the front surface plate 11, the touch panel 12, the adhesive layer 13, and the display 14 are adhered to each other to form the display unit 10. Next, the rear surface of the display unit 10 (specifically, the rear surface of the display 14) is adhered to the bottom surface section 31 of the attaching member 30 by using the adhesive layer 15, and thereby, as illustrated in FIG. 5, the display unit 10 is mounted on the attaching member 30 to obtain an integral structure.

Subsequently, as illustrated in FIG. 16, the short side 30A (side in which the first attaching sections 33 are provided) of the attaching member 30 is inserted into the cabinet 2C from obliquely upper position (arrow A4), and the nails of the first attaching sections 33 are hung on the concave section 45 by using the inclined section 45B at the entrance as a guide.

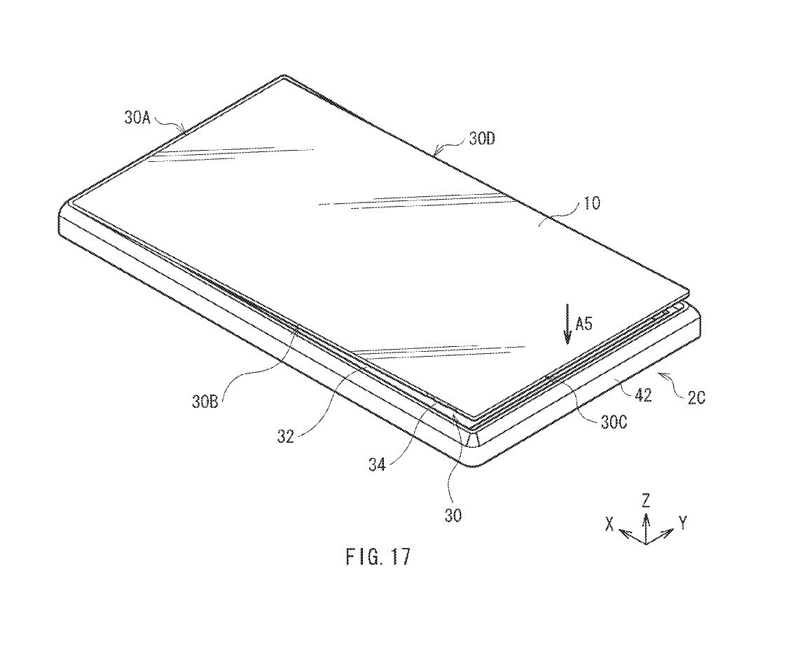

Thereafter, as illustrated in FIG. 17, the short side 30C of the attaching member 30 is lowered (arrow A5). At this time, since the second attaching sections 34 and 35 are inclined or curved from the rim section 32 outward, the second attaching sections 34 and 35 are hung on opening of the cabinet 2C, and further entry of the second attaching sections 34 and 35 is interrupted.

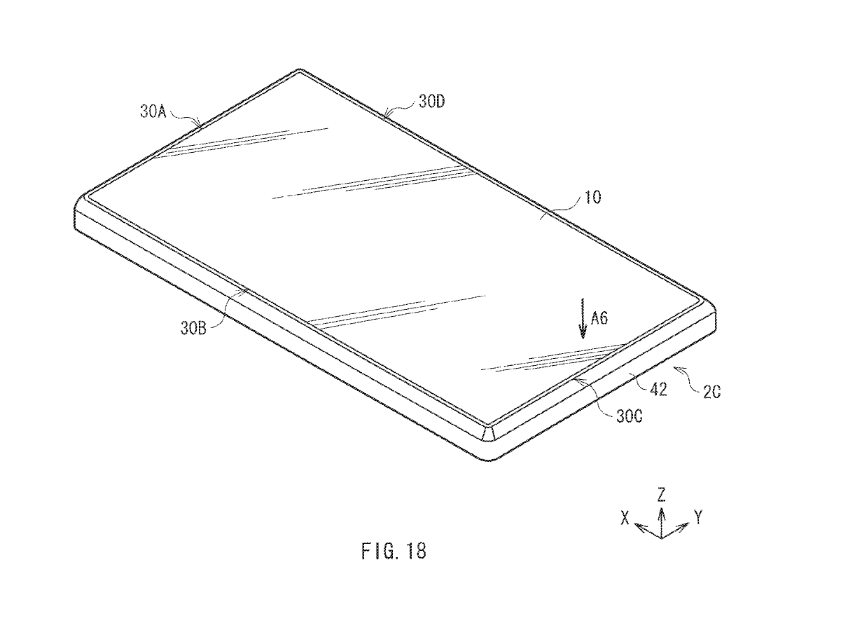

Subsequently, as illustrated in FIG. 18, when the short side 30C of the attaching member 30 is pressed downward (arrow A6), the second attaching sections 34 and 35 climb over the flange 43, and are fitted in the concave section 45 by elasticity of the plate spring of the second attaching sections 34 and 35 (snap-fit method). Thereby, as illustrated in FIG. 13, the second attaching sections 34 of the long sides 30B and 30D are retained by the retainer section 45D, and the lower end 32B of the rim section 32 is contacted with the seat section 45C. Further, as illustrated in FIG. 15, the second attaching section 35 of the short side 30C is retained by the retainer section 45D, and the end of the front surface plate 11 is contacted with the step section 44. At the same time, as illustrated in FIG. 11, the first attaching sections 33 are contacted with the contacting section 45A, the lower end 32B of the rim section 32 is contacted with the seat section 45C, and the rim section 32 of the short side 30A is fitted in the concave section 45.

Thereby, the first attaching sections 33 are fixed to the cabinet 2C, and the second attaching sections 34 and 35 are held between the rim section 32 and the cabinet 2C by elasticity. Accordingly, the display unit 10 is held and contained in a prescribed position in the cabinet 2C by the attaching member 30, and the display system 7 is completed.

In the display system 7, in the display 14, light from the backlight unit 17 may enter the liquid crystal display panel 16, and pass through the liquid crystal layer (not illustrated) while being modulated for every pixel based on an image voltage (in the case of a liquid crystal display panel). Alternatively, in the display 14, light may be generated from the organic EL panel (not illustrated). The light passes through the touch panel 12 and the front surface plate 11, is extracted outside of the display system 7, and is observed as an image. In this way, image display operation is performed. Further, in the touch panel 12, for example, in the case where a finger or the like is contacted with (or comes close to) the front surface plate 11, such an event is detected based on capacity change, and information input operation is performed.

In this embodiment, the attaching member 30 is provided between the display unit 10 and the cabinet 2C. The attaching member 30 has the rim section 32 opposed to the side surface of the display unit 10. The first attaching sections 33 and the second attaching sections 34 and 35 are provided in the rim section 32. The first attaching sections 33 are configured to be fixed to the cabinet 2C. The second attaching sections 34 and 35 are configured to be held between the rim section 32 and the cabinet 2C by elasticity. Since the rim section 32 of the attaching member 30 is provided in opposition to the side surface of the display unit 10, occupied width of the attaching member 30 in the bezel region is narrowed, compared to an existing display system that an end of a framework flat member is extended in a horizontal direction around a display unit. Therefore, the width of the bezel region is narrowed.

FIG. 19 describes the width of the bezel region in the display system 7. In the display system 7, as described above, as the non-translucent section 11B, the non-translucent layer 11C made of an opaque material such as a metal, a pigment, and a colorant is provided on the rear surface in the surrounding region of the front surface plate 11. Total width W2 of width W1 of the non-translucent layer 11C and the width of the cabinet 2C becomes the width of the bezel region.

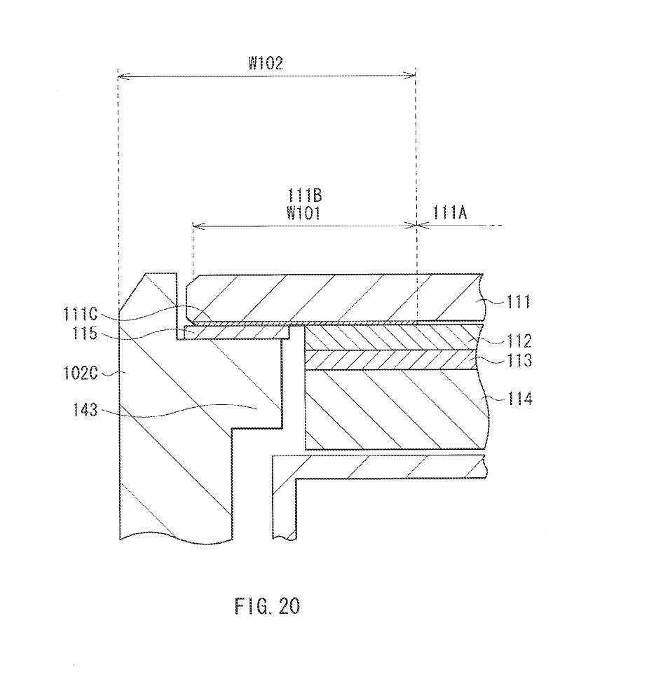

In an existing display system, for example, as illustrated in FIG. 20, a front surface plate 111 is adhered to the upper surface of a flange 143 of a cabinet 102C by using an adhesive layer 115 such as a double-faced tape. Therefore, width W101 of a non-translucent layer 111C has to be widened so that the adhesive layer 115 and the end of a display unit 110 are allowed to be hidden. As a result, width W102 of a bezel region is widened. It is to be noted that in FIG. 20, elements corresponding to those of the present embodiment are affixed with symbols having numbers obtained by adding 100 to those of the present embodiment.

In contrast, in the present embodiment, as illustrated in FIG. 19, it is only necessary for the width W1 of the non-translucent section 11C to have a size by which the rim section 32 of the attaching member 30 and the end of the display unit 10 are allowed to be hidden. Therefore, the width W2 of the bezel region is allowed to be narrowed extremely.

As described above, in the present embodiment, the rim section 32 of the attaching member 30 is provided in opposition to the side surface of the display unit 10, and the first attaching sections 33 configured to be fixed to the cabinet 2C and the second attaching sections 34 and 35 configured to be held between the rim section 32 and the cabinet 2C by elasticity are provided in the rim section 32. Therefore, the bezel is allowed to be narrowed. Thereby, the whole display system 7 is further down-sized without changing the screen size of the display unit 10. Therefore, configuring the image pickup system 1 by using the display system 7 allows the screen size to be increased while keeping portability.

### Second Embodiment

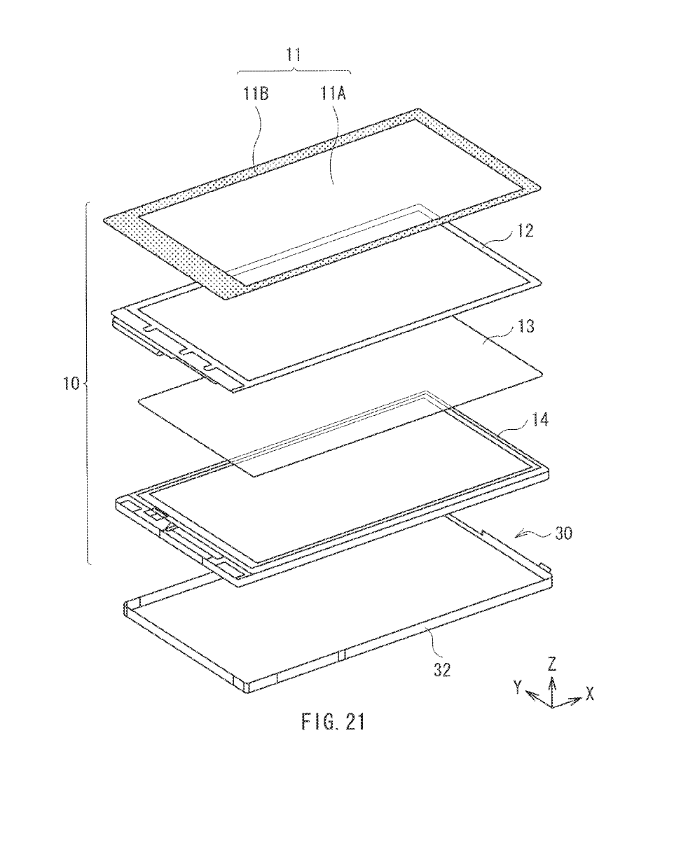

FIG. 21 illustrates the disassembled display unit 10 of the display system 7 according to a second embodiment of the present disclosure together with the attaching member 30. In this embodiment, a further reduction in thickness is achieved in addition to a narrowed bezel and downsizing by configuring the attaching member 30 of only the rim section 32 and omitting the bottom surface section 31. Except for this point, the display system 7 according to this embodiment has a configuration similar to that of the foregoing first embodiment. Therefore, a description will be given by affixing the same symbols to corresponding elements.

The cabinet 2C has the bottom surface section 41, the side surface section 42, the flange 43, the step section 44, and the concave section 45 as in the first embodiment. The bottom surface section 41, the side surface section 42, the flange 43, the step section 44, and the concave section 45 have respective configurations similar to those of the first embodiment.

The display unit 10 has the front surface plate 11, the touch panel 12, the adhesive layer 13, and the display 14 in this order from the front to the backward in the Z direction as in the first embodiment. The front surface plate 11, the touch panel 12, the adhesive layer 13, and the display 14 have respective configurations similar to those of the first embodiment. The attaching member 30 is provided behind the display unit 10 (specifically, behind the display 14).

The attaching member 30 may have, for example, the rim section 32 opposed to the side surfaces of the display unit 10, and does not have the bottom surface section 31. That is, the attaching member 30 has a shape of a window frame surrounding side surfaces of the display unit 10, and the screen display surface and the rear surface of the display unit 10 are opened. Thereby, in this embodiment, the whole thickness is decreased by a thickness of the bottom surface section 31 and a thickness of the adhesive layer 15, and the display system 7 is allowed to be further reduced in thickness.

It is to be noted that the display unit 10 may be fixed to inside of the rim section 32 of the attaching member 30 by using a double-faced tape, an adhesive (not illustrated either), or the like.

Preferably, as in the first embodiment, the attaching member 30 may be made of a plate such as stainless steel, since this is advantageous in terms of reinforcement and countermeasure against static electricity, and the attaching member 30 is allowed to be reduced in thickness. In the case where thickness limitation of the attaching member 30 is not tight, the attaching member 30 may be made of a resin.

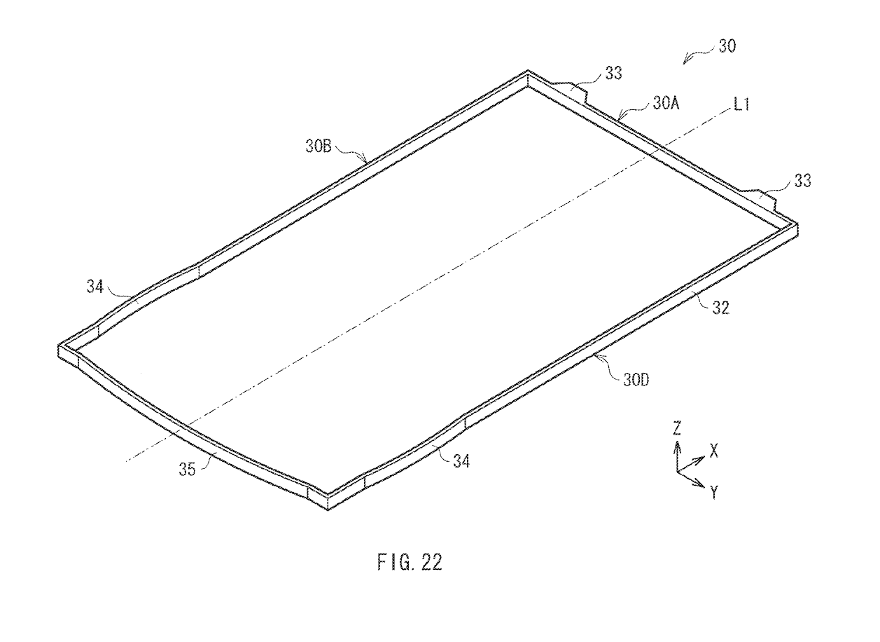

FIG. 22 illustrates an enlarged whole configuration of the attaching member 30 illustrated in FIG. 21. The first attaching sections 33 are provided in one short side 30A of the rim section 32, the second attaching sections 34 are provided in two opposing long sides 30B and 30D, and the second attaching section 35 is provided in the other short side 30C. The first attaching sections 33 are fixed to the cabinet 2C. The second attaching sections 34 and 35 are held between the rim section 32 and the cabinet 2C by elasticity. Thereby, in the display system 7, the bezel is allowed to be narrowed.

Desirably, the first attaching sections 33 may be provided, for example, in both ends of the short side 30A. Thereby, in the assembly step (see FIG. 16), rotation in the XY plane is allowed to be suppressed. Further, desirably, the first attaching sections 33 may be arranged in the same shape, being equally distant from both ends of the short side 30A (arranged line-symmetrically with respect to the center line L1 in the Y direction of the attaching member 30).

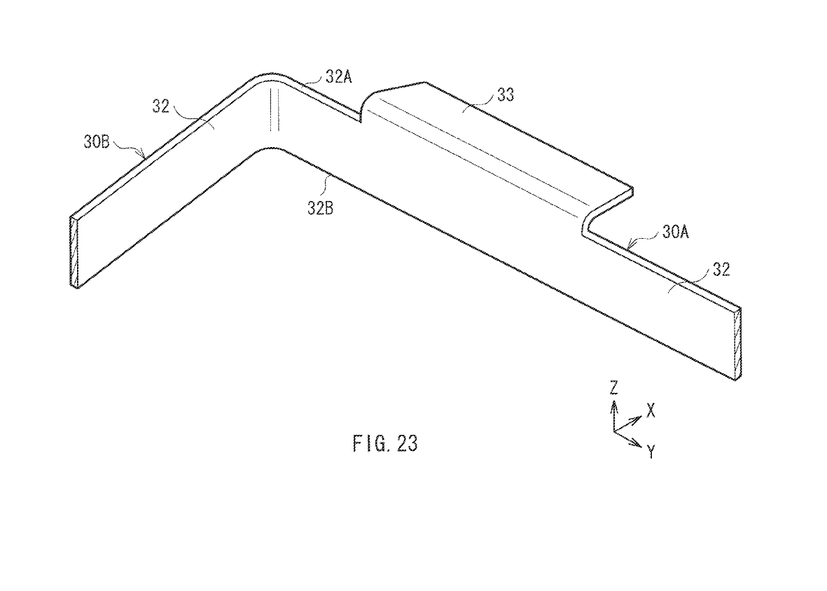

As illustrated in an enlarged view of FIG. 23, specifically, the first attaching section 33 is a nail extending outward from one end (upper end) 32A in the width direction of the rim section 32. For example, the first attaching section 33 may be bent perpendicular to the rim section 32.

Desirably, the second attaching sections 34 may be provided, for example, in ends on the short side 30C side of the long sides 30B and 30D. Further, desirably, the second attaching sections 34 may have the same shape, and may be arranged in positions opposed to each other in the long sides 30B and 30D (arranged line-symmetrically with respect to the center line L1 in the Y direction of the attaching member 30).

The second attaching section 35 may be provided in, for example, almost whole area of the short side 30C.

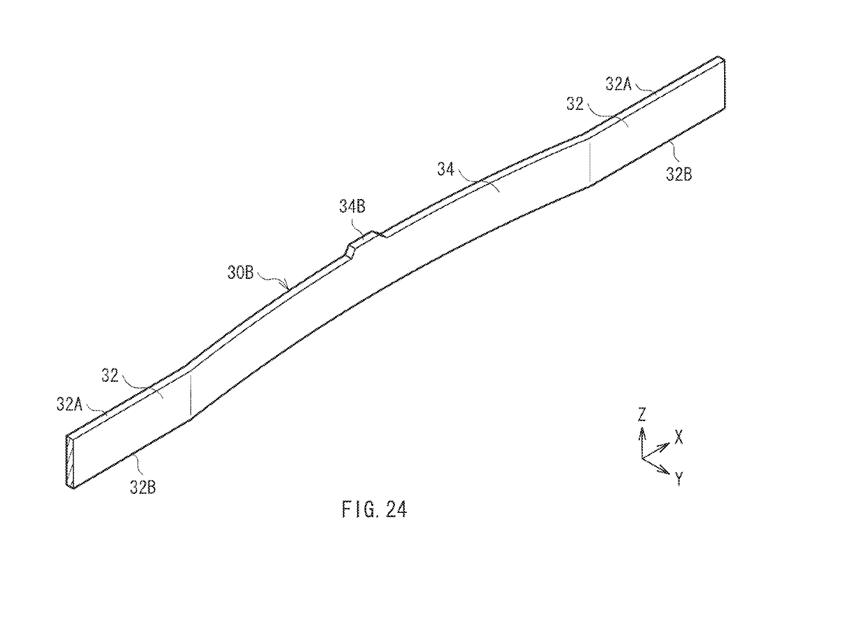

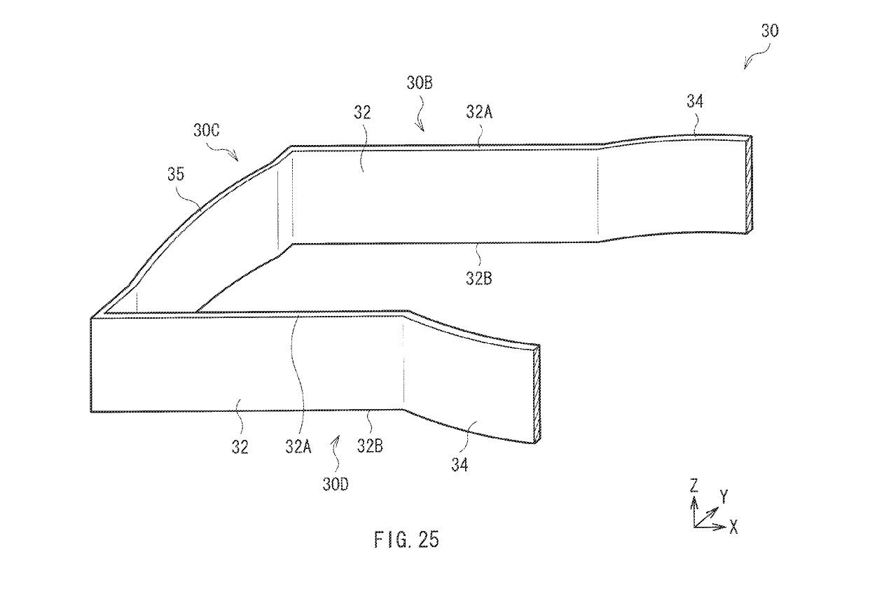

The second attaching sections 34 and 35 are, specifically, as illustrated in an enlarged views of FIG. 24 and FIG. 25, plate springs obtained by inclining or curving part of the rim section 32 outward. By forming the second attaching sections 34 and 35 as the plate springs, dimension variation due to a common difference of parts is allowed to be resolved.

As illustrated in FIG. 24, preferably, the second attaching section 34 may have a projection 34B in the center thereof, since thereby, contact position of the projection 34B is allowed to be constant.

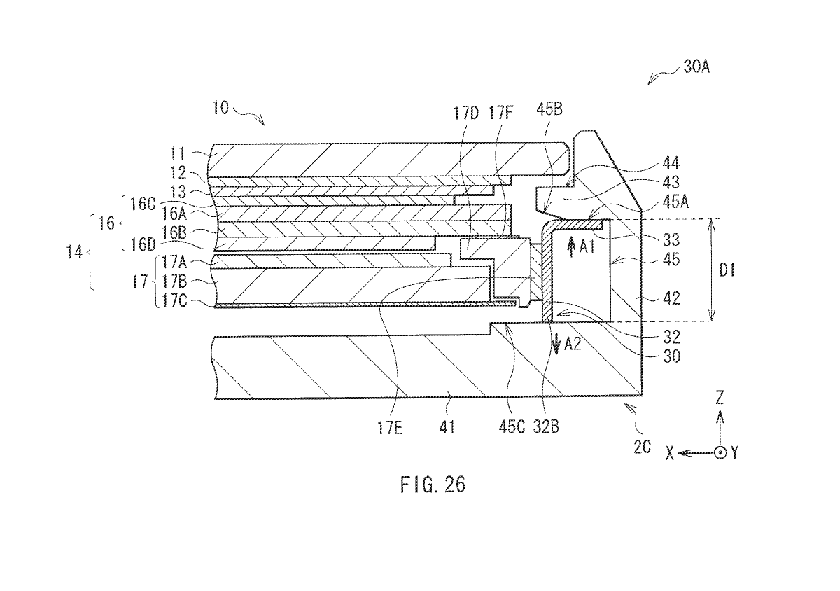

FIG. 26 illustrates a state of fitting of the rim section 32 into the cabinet 2C in the first attaching section 33. In the short side 30A of the attaching member 30, the contacting section 45A to which the nail of the first attaching section 33 is contacted is provided on the upper surface of the concave section 45 (lower surface of the flange 43). By contacting the contacting section 45A with the first attaching section 33, upward movement (arrow A1) of the attaching member 30 is allowed to be restricted.

The contacting section 45A may be, for example, a flat surface capable of making surface-contact with the first attaching section 33. Desirably, the inclining section 45B as a fitting guide for the first attaching section 33 may be provided at the entrance of the contacting section 45A.

The seat section 45C receiving the other end (lower end) in the width direction of the rim section 32 is provided on the lower surface of the concave section 45. By contacting the seat section 45C with the lower end 32B of the rim section 32, downward movement (arrow A2) of the attaching member 30 is allowed to be restricted. Therefore, it is sufficient for the front surface plate 11 to be moderately fitted in the step section 44 above the flange 43, and it is not necessary for the front surface plate 11 to be brought into contact with the flange 43 or the like.

Preferably, the distance D1 between the contacting section 45A and the seat section 45C may correspond to the height of the rim section 32 (distance between the first attaching section 33 and the lower end 32B). Thereby, by contacting the first attaching section 33 with the contacting section 45A and by contacting the lower end 32B of the rim section 32 with the seat section 45C, the rim section 32 is fitted in the concave section 45. Therefore, slip in the Z direction of the attaching member 30 and the display unit 10 is allowed to be suppressed.

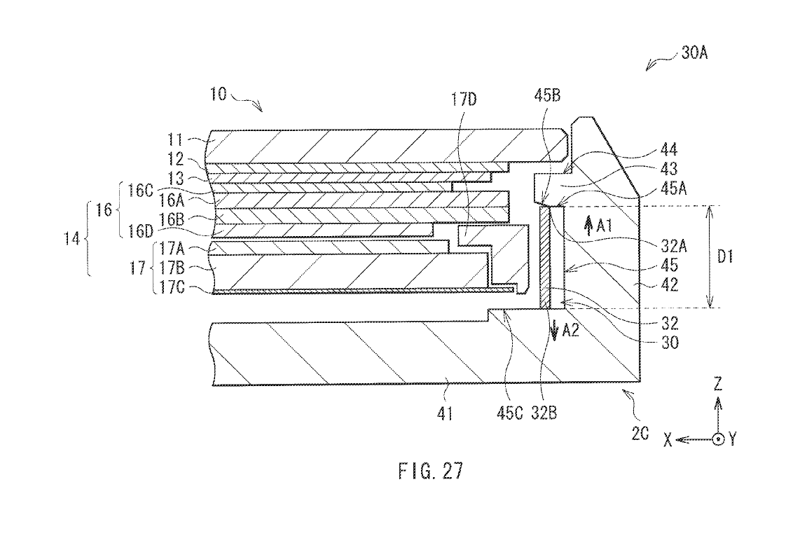

FIG. 27 illustrates a state of fitting of the rim section 32 into the cabinet 2C in the vicinity of the first attaching section 33. In portions other than the first attaching members 33 of the short side 30A, the upper end 32A of the rim section 32 may be contacted with the contacting section 45A. The inclining section 45B as a fitting guide for the upper end 32A of the rim section 32 may be provided at the entrance of the contacting section 45A. The lower end 32B of the rim section 32 may be contacted with the seat section 45C.

The distance D1 between the contacting section 45A and the seat section 45C may correspond to the height of the rim section 32 (distance between the upper end 32A and the lower end 32B of the rim section 32) similarly to the description for the first attaching section 33.

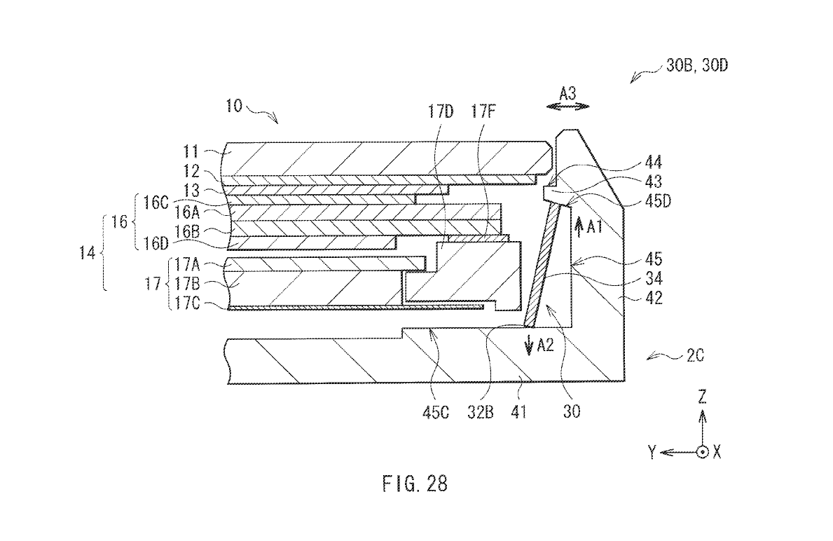

FIG. 28 illustrates a state of attachment of the rim section 32 to the cabinet 2C in the second attaching section 34. In the long sides 30B and 30D of the attaching member 30, the retainer section 45D retaining the plate spring of the second attaching section 34 is provided on the upper surface of the concave section 45. By contacting the retainer section 45D with the second attaching section 34, upward movement (arrow A1) of the attaching member 30 and movement in the XY plane direction (arrow A3) of the attaching member 30 are allowed to be restricted.

Desirably, the retainer section 45D may have an inclined surface as a fitting guide for the second attaching section 34.

The seat section 45C receiving the lower end 32B of the rim section 32 is provided on the lower surface of the concave section 45. By contacting the seat section 45C with the lower end 32B of the rim section 32, downward movement (arrow A2) of the attaching member 30 is allowed to be restricted. Therefore, it is sufficient for the front surface plate 11 to be moderately fitted in the step section 44 above the flange 43, and it is not necessary for the front surface plate 11 to be brought into contact with the flange 43 or the like.

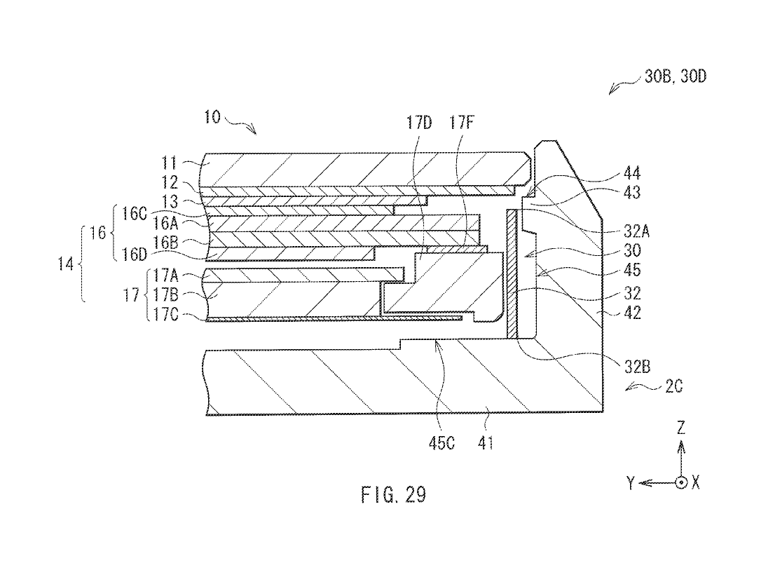

FIG. 29 illustrates a state of attachment of the rim section 32 to the cabinet 2C in the vicinity of the second attaching section 34. In portions other than the second attaching members 34 of the long sides 30B and 30D, the upper end 32A of the rim section 32 is not contacted with any place, and is opened. Thereby, the rim section 32 is allowed to have effect as a shield case to suppress static electricity. The lower end 32B of the rim section 32 may be contacted with the seat section 45C.

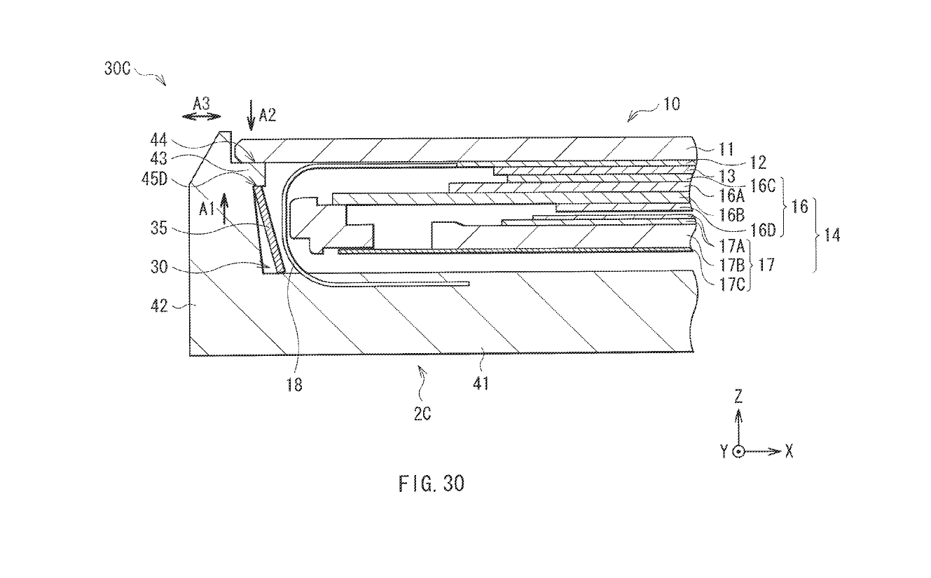

FIG. 30 illustrates a state of attachment of the rim section 32 to the cabinet 2C in the second attaching section 35. In the short side 30C of the attaching member 30, the retainer section 45D retaining the plate spring of the second attaching section 35 is provided on the upper surface of the concave section 45. By contacting the retainer section 45D with the second attaching section 35, upward movement (arrow A1) of the attaching member 30 and movement in the XY plane direction (arrow A3) of the attaching member 30 are allowed to be restricted.

Preferably, in the short side 30C, the step section 44 may receive the end of the front surface plate 11. By contacting the step section 44 with the end of the front surface plate 11, downward movement (arrow A2) of the attaching member 30 and the display unit 10 is allowed to be restricted. It is to be noted that the downward movement is allowed to be suppressed sufficiently only by laying the front surface plate 11 on the step section 44, and fixing by an adhesive or the like is not necessarily performed.

A manufacturing method (assembly method) and operation of the display system 7 are, for example, similar to those of the first embodiment.

As described above, in this embodiment, the attaching member 30 has a shape of a window frame surrounding side surfaces of the display unit 10. Therefore, in addition to the narrowed bezel and downsizing as some effects of the first embodiment, the whole thickness is decreased by portions of a thickness of the bottom surface section 31 and a thickness of the adhesive layer 15, and the display system 7 is allowed to be further reduced in thickness. Accordingly, configuring the image pickup system 1 by using the display system 7 allows a thickness reduction to be achieved in addition to the high portability and the large screen size as some effects of the first embodiment.

### Modification 1

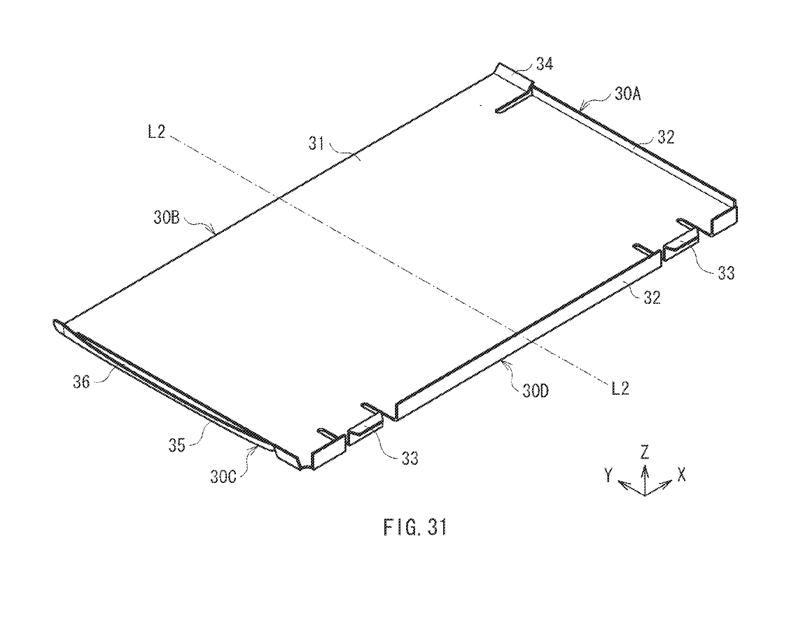

FIG. 31 illustrates a whole configuration of the attaching member 30 according to a modification 1 of the above-described embodiment of the disclosure. In the attaching member 30, the first attaching sections 33 are provided in the long side 30D, and thereby, rotation in the XY plane is allowed to be suppressed in the assembly step (see FIG. 16). Except for this point, a configuration, operation, and effects of the attaching member 30 are similar to those of the first embodiment.

Desirably, the first attaching sections 33 may be provided, for example, in both ends of the long side 30D as in the first embodiment. Thereby, in the assembly step (see FIG. 16), rotation in the XY plane is allowed to be suppressed more securely. Further, desirably, the first attaching sections 33 may be arranged in the same shape, being equally distant from both ends of the long side 30D (arranged line-symmetrically with respect to center line L2 in the X direction of the attaching member 30).

### Modification 2

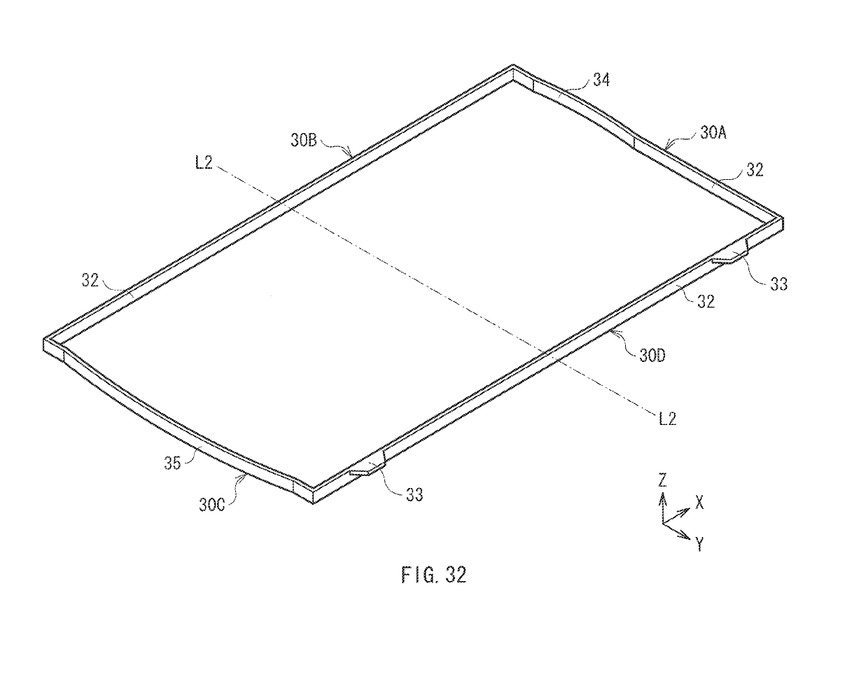

FIG. 32 illustrates a whole configuration of the attaching member 30 according to a modification 2 of the above-described embodiment of the disclosure. In the attaching member 30, the first attaching sections 33 in the second embodiment are provided in the long side 30D as in the modification 1, and thereby, rotation in the XY plane is allowed to be suppressed in the assembly step (see FIG. 16). Except for this point, a configuration, operation, and effects of the attaching member 30 are similar to those of the second embodiment.

It is to be noted that in the foregoing modifications 1 and 2, the description has been given of the case that the first attaching sections 33 are provided in the long side 30D, and the second attaching sections 34 and 35 are provided in the short sides 30A and 30C. Alternatively, the first attaching sections 33 may be provided in the long side 30D, and the second attaching sections 34 and 35 may be provided in the long side 30B opposed thereto.

The present disclosure has been described with reference to the example embodiments. However, the present disclosure is not limited to the foregoing embodiments, and various modifications may be made. For example, in the foregoing first embodiment and the foregoing second embodiment, the description has been given of the case that the second attaching sections 34 are provided in the long sides 30B and 30D of the attaching member 30, and the second attaching section 35 is provided in the short side 30C. Alternatively, the second attaching section 35 of the short side 30C may be omitted.

Further, for example, in the foregoing first embodiment, the description has been given of the case that the short side 30C of the attaching member 30 is provided with the opening 36 to give passage to a flexible printed circuit. Alternatively, instead of the opening 36, a notch may be provided. In this case, the short side 30C may be provided with only the notch, or the second attaching section 35 may be arranged on a single side or both sides of the notch.

Further, for example, in the foregoing embodiments, the description has been given of the case that the rim section 32 is provided in four sides of the bottom surface section 31. Alternatively, the rim section 32 may be provided only in a side in which the first attaching sections 33 or the second attaching sections 34 and 35 are arranged (see FIG. 31 of the modification 1).

In addition thereto, for example, in the foregoing embodiments, water-proof specifications may be applied by encapsulating a sealant (not illustrated) in the concave section 45, for example.

Furthermore, for example, in the foregoing embodiments, the description has been given of the case that the display unit 10 and the attaching member 30 have rectangle shapes. However, the shape of the display unit 10 and the attaching member 30 is not limited to the rectangle shape, and may be a polygonal shape such as a hexagonal shape and a circle.

In addition thereto, further, for example, in the foregoing embodiments, the description has been given of the case that the display unit 10 is configured of liquid crystal or organic EL. Alternatively, instead of the liquid crystal or the organic EL, the display unit 10 may be configured by using other display devices, which may include plasma, inorganic EL, electrodeposition, and electrochromic.

Furthermore, for example, in the foregoing embodiments, the description has been given of the digital still camera as an example of the image pickup system 1. Alternatively, the present disclosure is applicable to other image pickup systems, which may include a digital single-lens reflex camera and a video camcorder. For example, in the video camcorder, the present disclosure is widely applicable to any product by using the attaching member 30 and standardizing attachment to the cabinet 2C. Further, in the digital single-lens reflex camera, since a large screen is achievable while securing a wide grip section due to a narrowed bezel, grip is facilitated and a monitor screen is easily viewable.

In addition thereto, further, the display system 7 according to the example embodiments of the present disclosure is not limited to the application as a display monitor of the image pickup system 1, and is also applicable to other systems, which may include a PC, a tablet, a smartphone, and the like. In particular, the display system 7 is extremely suitable for the smartphone in which achieving a narrowed bezel has been advanced rapidly. In addition thereto, the display system 7 is applicable to other display systems of apparatuses, which may include a television, a wall monitor system, a mobile phone, a telephone, a fax machine, a car navigation system, a game machine, a digital photo frame, an electric bulletin board, and the like.

Furthermore, the technology encompasses any possible combination of some or all of the various embodiments described herein and incorporated herein.

It is possible to achieve at least the following configurations from the above-described example embodiments of the disclosure.

(1) A display system, including:

a display unit;

a holding member containing the display unit; and

an attaching member provided between the display unit and the holding member,

wherein the attaching member includes
a rim section opposed to a side surface of the display unit,
a first attaching section provided in the rim section and configured to be fixed to the holding member, and
a second attaching section provided in the rim section and configured to be held between the rim section and the holding member by elasticity.
   (2) The display system according to (1), wherein the rim section has a shape of a window frame that surrounds the side surface of the display unit.
   (3) The display system according to (1) or (2), wherein

the attaching member has a rectangular flat shape having a long side in one direction, and

the first attaching section is provided in the long side of the attaching member.

(4) The display system according to any one of (1) to (3), wherein the second attaching section is provided in two opposing sides of the attaching member.
(5) The display system according to any one of (1) to (4), wherein the holding member includes a concave section configured to receive the first attaching section and the second attaching section.
(6) The display system according to (5), wherein

the first attaching section is a nail extending outward from a first end that is located in a width direction of the rim section, and

the concave section includes a contacting section to which the nail is contacted.

(7) The display system according to (6), wherein the concave section includes a seat section configured to receive a second end that is located in the width direction of the rim section.
(8) The display system according to (7), wherein the rim section is fitted in the concave section by contacting of the first attaching section with the contacting section and by contacting of the second end of the rim section with the seat section.
(9) The display system according to any one of (5) to (8), wherein
the second attaching section is a plate spring in which a part of the rim section is inclined outward or curved outward, and
the concave section includes a retainer section configured to retain the plate spring.
   (10) The display system according to any one of (1), (2), and (4) to (9), wherein

the attaching member has a rectangular flat shape having a long side in one direction, and

the first attaching section is provided in a short side of the attaching member.

(11) The display system according to any one of (1) to (10), wherein

the attaching member includes a bottom surface section that covers a rear surface of the display unit, and

the rear surface of the display unit is adhered to the bottom surface section.

(12) The display system according to (11), wherein the attaching member includes an opening that gives passage to a flexible printed circuit therethrough.
(13) The display system according to any one of (1) to (12), wherein

the display unit includes a display and a front surface plate, the front surface plate being provided on an image display surface side of the display, and

the holding member includes a step section configured to receive an end of the front surface plate.

(14) An image pickup system provided with an image pickup optical system, an image pickup device, and a display system that displays one of a subject image formed by the image pickup optical system and an image picked up by the image pickup device, the display system including:

a display unit;

a holding member containing the display unit; and

an attaching member provided between the display unit and the holding member,

wherein the attaching member includes
a rim section opposed to a side surface of the display unit,
a first attaching section provided in the rim section and configured to be fixed to the holding member, and
a second attaching section provided in the rim section and configured to be held between the rim section and the holding member by elasticity.

The present disclosure contains subject matter related to that disclosed in Japanese Priority Patent Application JP 2012-141158 filed in the Japan Patent Office on Jun. 22, 2012, the entire contents of which is hereby incorporated by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A display system, comprising:
a display unit;
a holding member containing the display unit; and
an attaching member provided between the display unit and the holding member,
wherein the attaching member includes
a rim section opposed to a side surface of the display unit,
a first attaching section provided in the rim section and configured to be fixed to the holding member, and
a second attaching section provided in the rim section and configured to be held between the rim section and the holding member by elasticity.

2. The display system according to claim 1, wherein the rim section has a shape of a window frame that surrounds the side surface of the display unit.

3. The display system according to claim 1, wherein
the attaching member has a rectangular flat shape having a long side in one direction, and
the first attaching section is provided in the long side of the attaching member.

4. The display system according to claim 1, wherein the second attaching section is provided in two opposing sides of the attaching member.

5. The display system according to claim 1, wherein the holding member includes a concave section configured to receive the first attaching section and the second attaching section.

6. The display system according to claim 5, wherein
the first attaching section is a nail extending outward from a first end that is located in a width direction of the rim section, and
the concave section includes a contacting section to which the nail is contacted.

7. The display system according to claim 6, wherein the concave section includes a seat section configured to receive a second end that is located in the width direction of the rim section.

8. The display system according to claim 7, wherein the rim section is fitted in the concave section by contacting of the first attaching section with the contacting section and by contacting of the second end of the rim section with the seat section.

9. The display system according to claim 5, wherein
the second attaching section is a plate spring in which a part of the rim section is inclined outward or curved outward, and
the concave section includes a retainer section configured to retain the plate spring.

10. The display system according to claim 1, wherein
the attaching member has a rectangular flat shape having a long side in one direction, and
the first attaching section is provided in a short side of the attaching member.

11. The display system according to claim 1, wherein
the attaching member includes a bottom surface section that covers a rear surface of the display unit, and
the rear surface of the display unit is adhered to the bottom surface section.

12. The display system according to claim 11, wherein the attaching member includes an opening that gives passage to a flexible printed circuit therethrough.

13. The display system according to claim 1, wherein
the display unit includes a display and a front surface plate, the front surface plate being provided on an image display surface side of the display, and
the holding member includes a step section configured to receive an end of the front surface plate.

14. An image pickup system provided with an image pickup optical system, an image pickup device, and a display system that displays one of a subject image formed by the image pickup optical system and an image picked up by the image pickup device, the display system comprising:
a display unit;
a holding member containing the display unit; and
an attaching member provided between the display unit and the holding member,
wherein the attaching member includes
a rim section opposed to a side surface of the display unit,
a first attaching section provided in the rim section and configured to be fixed to the holding member, and
a second attaching section provided in the rim section and configured to be held between the rim section and the holding member by elasticity.
